(19) United States
(12) Patent Application Publication
(10) Pub. No.: US 2026/0140184 A1
(43) Pub. Date: May 21, 2026

(54) ECCENTRICITY MEASUREMENT SYSTEM

(71) Applicant: HYUNDAI MOBIS CO., LTD., Seoul (KR)

(72) Inventor: Sanghan LEE, Yongin-si (KR)

(73) Assignee: HYUNDAI MOBIS CO., LTD., Seoul (KR)

(21) Appl. No.: 19/387,889

(22) Filed: Nov. 13, 2025

(30) Foreign Application Priority Data
Nov. 18, 2024 (KR) 10-2024-0164143
Nov. 18, 2024 (KR) 10-2024-0164151

(51) Int. Cl. G01R 31/34

(52) U.S. Cl. CPC G01R 31/343

(57) ABSTRACT

The present disclosure The eccentricity measurement system comprises an eccentricity measurement sensor fitted with a shoe of the stator and configured to measure a presence or absence of eccentricity of the rotor by measuring a change in magnetic field generated between the rotor and the stator, a first sensing terminal formed integrally with a terminal assembly of the stator and configured to transfer sensing information of the eccentricity measurement sensor to the outside, a second sensing terminal having one surface that adjoins an axial distal end surface of the stator, the second sensing terminal being configured to transfer sensing information of the eccentricity measurement sensor to the first sensing terminal, and a connection substrate configured to electrically connect the first sensing terminal and the second sensing terminal.

### CROSS REFERENCE TO RELATED APPLICATION

The present application claims priority to Korean Patent Application No. 10-2024-0164151, filed Nov. 18, 2024 and Korean Patent Application No. 10-2024-0164143, filed Nov. 18, 2024, the entire contents of which is incorporated herein for all purposes by this reference.

### BACKGROUND OF THE DISCLOSURE

### Field of the Disclosure

The present disclosure relates to an eccentricity measurement system, and more particularly, to an eccentricity measurement system configured to measure eccentricity occurring in a motor rotor.

### Description of the Related Art

Reflective laser displacement sensors are being widely used for methods of measuring rotor eccentricities of permanent magnet electric motors. This method measures variations in distance by irradiating a rotary shaft directly with laser beams. The method has an advantage of being intuitively understandable and applicable to various rotary devices. In addition, transmissive micrometers or transmissive 2D micrometers are also used in industrial sites.

However, in case that an outer diameter of a rotor core other than a shaft is measured when a reflective laser displacement sensor in the related art is applied to a permanent magnet electric motor, a sensor needs to be mounted outside a housing of an electric motor, and a surface of the rotor core needs to be irradiated with laser beams. However, because the rotor core is covered by a stator in the structure of the electric motor, the laser beams cannot penetrate the rotor core, and the measurement cannot be performed. In particular, there is a problem in that it is difficult to measure static eccentricity because it is impossible to measure a radial displacement at a single point.

For this reason, at least two or more sensors are required to be provided on two opposite sides even though a portion of the shaft that is not covered by the stator core. In this case, the sensor may interfere with other external components, which imposes a restriction on a sensor mounting structure and leads to an increase in costs of the system.

### DOCUMENT OF RELATED ART

[Patent Document] Japanese Patent No. 6441757 “Eccentricity Direction Detection Device and Variable Gap Motor”

### SUMMARY OF THE DISCLOSURE

The present disclosure is proposed to solve these problems and aims to provide an eccentricity measurement system including an eccentricity measurement sensor mounted in a motor and configured to measure all tilt eccentricity, static eccentricity, and dynamic eccentricity of a rotor by using a change in magnetic field generated between the rotor and a stator, thereby overcoming a limitation of a reflective laser sensor method in the related art, reducing costs in comparison with the reflective laser sensor in the related art, detecting an eccentricity factor that most significantly affects noise and vibration of a rotary device, detecting a defect at an initial stage of mass production to prevent shipment of potentially defective products, measuring eccentricity caused by abrasion or the like after product durability testing or after prolonged operation of a vehicle to detect in advance a problem, and taking in advance an action such as repair.

With the above-described eccentricity measurement system, when the eccentricity measurement system is applied to autonomous vehicles in the future, it is possible to monitor a mechanical state of a rotary device, apply the eccentricity measurement system to a smart rotary device system capable of evaluating a state thereof by using a pre-secured defect level index, and recognize the state of the rotary device in a region imperceptible to humans. Furthermore, the eccentricity measurement system may be applied in a case in which it is difficult to recognize a state of an individual rotary device because of external vibration or noise, such that the eccentricity measurement system may be used to detect and address problems in an electric motor used in urban air mobility (UAM) aircraft in advance.

In order to achieve the above-mentioned object, one embodiment of the present disclosure provides an eccentricity measurement system, which is applied to a motor system including a stator and a rotor and measures eccentricity of the rotor, the eccentricity measurement system including: an eccentricity measurement sensor fitted with a shoe of the stator and configured to measure the presence or absence of eccentricity of the rotor by measuring a change in magnetic field generated between the rotor and the stator; a first sensing terminal formed integrally with a terminal assembly of the stator and configured to transfer sensing information of the eccentricity measurement sensor to the outside; a second sensing terminal having one surface that adjoins an axial distal end surface of the stator, the second sensing terminal being configured to transfer sensing information of the eccentricity measurement sensor to the first sensing terminal; and a connection substrate configured to electrically connect the first sensing terminal and the second sensing terminal.

In addition, the first sensing terminal may include: an integrated housing formed with a predetermined electrode pattern by insert molding, formed integrally with the terminal assembly of the stator, and made of an insulating material; and an external terminal into which the electrode pattern is inserted and an electrode of an external component is inserted, and the integrated housing may include an arc portion formed in an arc shape along a circumferential edge of the stator.

In addition, the second sensing terminal may include: a flat plate-type substrate part electrically connected to the eccentricity measurement sensor and including a circuit pattern printed on one surface; and a mounting part formed in a shape corresponding to the substrate part, including a predetermined accommodation space configured to accommodate the substrate part, having a partition wall formed along an edge of the accommodation space, having one surface adjoining an axial distal end surface of the stator, and made of an insulating material.

In addition, the eccentricity measurement sensor may include a pin extending toward the second sensing terminal, and the substrate part may include a via hole formed through a surface adjoining the eccentricity measurement sensor, the via hole being configured such that the pin is fitted with the via hole and soldered.

In addition, the substrate part may include: a ring portion formed in a ring shape along the circumferential edge of the stator; and a sensor connection portion extending in a radial direction from the ring portion toward the eccentricity measurement sensor.

In addition, the connection substrate may include: a first connection part provided at one end and electrically connected to the first sensing terminal; a second connection part provided at the other end and electrically connected to the second sensing terminal; and a signal transmission part electrically connected to the first connection part and the second connection part and having therein an embedded wiring circuit.

In addition, the first sensing terminal may include a first internal terminal electrically connected to the electrode pattern and formed to be withdrawn to the outside of the arc portion, the integrated housing may include a first connector insertion groove protruding from one surface of the ring portion, formed outside the first internal terminal, and having an inner surface shape corresponding to an outer surface shape of the first connection part, and the first connection part may be a connector including a groove concavely formed in an axial direction so that the first internal terminal is inserted into the groove.

In addition, the second sensing terminal may include a second internal terminal electrically connected to the circuit pattern, the substrate part may include a second connector insertion groove concavely formed radially inward along an outer peripheral surface of the second internal terminal, the mounting part may be formed such that the partition wall in a region, which corresponds to a region in which the second connector insertion groove is formed, is formed to be lower than the partition wall in a region corresponding to a region in which the second connector insertion groove is not formed, and the second connection part may be a connector including a groove concavely formed in the radial direction so that the second internal terminal is inserted into the groove.

In addition, the mounting part may include at least one fixing portion extending from an inner surface of the accommodation space and configured to fix a position of the substrate part.

In addition, the fixing portion may include a first protruding portion including a curved surface having a predetermined curvature, and a width of a side of the first protruding portion, which adjoins the stator, and a width of a side of the first protruding portion, which does not adjoin the stator, may be equal to each other.

In addition, the fixing portion may include a second protruding portion including a curved surface having a predetermined curvature, and a width of a side of the second protruding portion, which does not adjoin the stator, may be smaller than a width of a side of the second protruding portion that adjoins the stator.

In addition, the fixing portion may include: a springback portion extending from the inner surface of the accommodation space of the mounting part; and a projection protruding from a distal end of the springback portion so as to adjoin one surface of the substrate part.

In addition, the eccentricity measurement sensor may be provided as two or more eccentricity measurement sensors disposed in the stator, and the respective eccentricity measurement sensors may be disposed to be spaced apart from one another at equal intervals.

In addition, the eccentricity measurement sensor may be provided as two or more eccentricity measurement sensors disposed in the stator and disposed to be spaced apart from one another while having a phase difference of 90 degrees.

### BRIEF DESCRIPTION OF THE DRAWINGS

FIG. 1 is an overall perspective view illustrating a stator to which an eccentricity measurement system of the present disclosure is applied.

FIG. 2 is an overall perspective view illustrating the eccentricity measurement system of the present disclosure.

FIG. 3 is a front view illustrating an eccentricity measurement sensor of the present disclosure.

FIG. 4 is a perspective view illustrating a first sensing terminal of the present disclosure.

FIG. 5 is a partial perspective view illustrating an external terminal of the present disclosure.

FIG. 6 is a perspective view illustrating a substrate part of a second sensing terminal of the present disclosure.

FIG. 7 is a perspective view illustrating a mounting part of the second sensing terminal of the present disclosure.

FIG. 8 is a partial perspective view illustrating a coupling relationship between the second sensing terminal and the eccentricity measurement sensor of the present disclosure.

FIG. 9 is a partial perspective view illustrating a first embodiment of a fixing portion of the present disclosure.

FIG. 10 is a partial perspective view illustrating a second embodiment of the fixing portion of the present disclosure.

FIG. 11 is a partial perspective view illustrating a third embodiment of the fixing portion of the present disclosure.

FIG. 12 is a perspective view illustrating a connection substrate of the present disclosure.

FIG. 13 is a partial perspective view illustrating a first internal terminal of the present disclosure.

FIG. 14 is a partial perspective view illustrating a second internal terminal of the present disclosure.

FIG. 15 is a partial perspective view illustrating a coupling relationship between the connection substrate, the first sensing terminal, and the second sensing terminal of the present disclosure.

FIGS. 16 to 18 are schematic views illustrating embodiments of an arrangement of the eccentricity measurement sensor of the present disclosure.

FIGS. 19 and 20 are schematic views illustrating a positional relationship between a rotor and the eccentricity measurement sensor in the event of tilt eccentricity.

FIG. 21 is a schematic view illustrating a positional relationship between the rotor and the eccentricity measurement sensor in the event of static eccentricity.

FIG. 22 is a schematic view illustrating a positional relationship between the rotor and the eccentricity measurement sensor in the event of dynamic eccentricity.

FIGS. 23 and 24 are schematic views illustrating graphs of magnetic flux amounts measured by two eccentricity measurement sensors in the event of tilt eccentricity.

FIG. 25 is a schematic view illustrating graphs of the magnetic flux amounts measured by the two eccentricity measurement sensors in the event of static eccentricity.

FIG. 26 is a schematic view illustrating graphs of the magnetic flux amounts measured by the two eccentricity measurement sensors in the event of dynamic eccentricity.

### DETAILED DESCRIPTION OF THE DISCLOSURE

Hereinafter, the technical spirit of the present disclosure will be described in more detail using the accompanying drawings. In addition, terms or words used in the specification and the claims should not be interpreted as being limited to a general or dictionary meaning and should be interpreted as a meaning and a concept which conform to the technical spirit of the present disclosure based on a principle that an inventor can appropriately define a concept of a term in order to describe his/her own Disclosure by the best method.

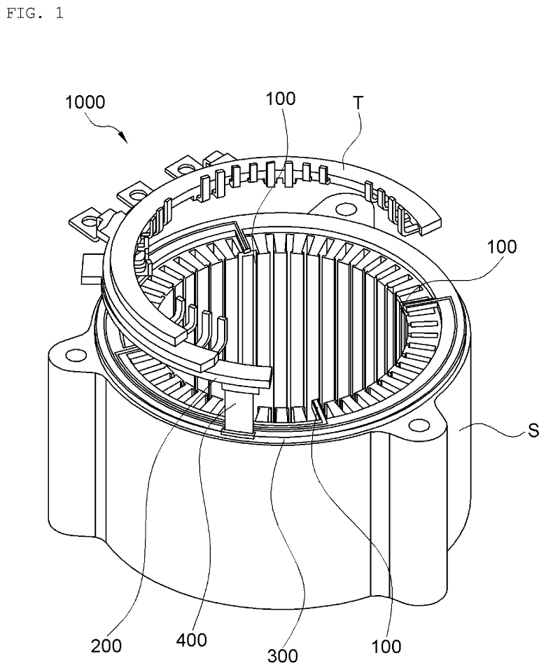

Hereinafter, a basic configuration of an eccentricity measurement system 1000 of the present disclosure will be described with reference to FIGS. 1 to 3.

The eccentricity measurement system 1000 of the present disclosure may be applied to a motor system including a stator S and a rotor R and measure eccentricity of the rotor R. As illustrated in FIG. 1, the eccentricity measurement system 1000 may include eccentricity measurement sensors 100, a first sensing terminal 200, a second sensing terminal 300, and a connection substrate 400. The eccentricity measurement sensor 100 may be fitted with a shoe of the stator S and measure the presence or absence of eccentricity of the rotor R by using a change in magnetic field generated between the rotor R and the stator S. In more detail, the eccentricity measurement sensor may be a magnetic flux sensor provided such that one surface thereof faces the rotor R, and an induced electromotive force is generated in a region including an upper end R1 and a lower end R2 of the rotor R based on an axial direction.

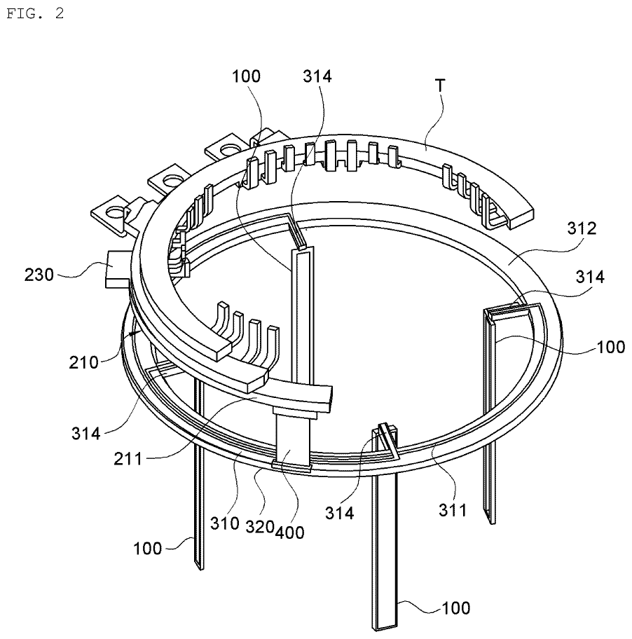

In addition, as illustrated in FIG. 2, the first sensing terminal 200 may be integrated with a terminal assembly T of the stator S and transfer sensing information of the eccentricity measurement sensor 100 to the outside. The second sensing terminal 300 may be electrically and structurally connected to the eccentricity measurement sensor 100, mounted on a surface perpendicular to an axis of the stator S, and configured to transfer sensing information of the eccentricity measurement sensor 100 to the first sensing terminal 200. In addition, the connection substrate 400 may electrically connect the first sensing terminal 200 and the second sensing terminal 300. In this case, the connection substrate 400 may be provided between the first sensing terminal 200 and the second sensing terminal 300, i.e., between the terminal assembly T and the stator S. In addition, the first sensing terminal 200 and the second sensing terminal 300 may each be formed in an arc or ring shape. Therefore, motor coils, which are wound around the first sensing terminal 200, the second sensing terminal 300, and the stator S, may not interfere with one another. Because the two sensing terminals, i.e., the first sensing terminal 200 and the second sensing terminal 300 are included as described above, the first sensing terminal 200, the terminal assembly T, the second sensing terminal 300, and the eccentricity measurement sensor 100 may be assembled in advance and mounted on the stator S, and then the first sensing terminal 200 and the second sensing terminal 300 may be connected to the connection substrate 400, thereby further simplifying an assembling process and remarkably reducing a probability of a defect.

In addition, because the first sensing terminal 200 and the second sensing terminal 300 are included, it is possible to easily transfer measurement information, which is measured by the eccentricity measurement sensor 100, to an external controller. Therefore, an induced electromotive force signal generated in sensor coils 120 of the eccentricity measurement sensor 100 may be analyzed, and the presence or absence of eccentricity of the rotor R may be identified. In addition, because the connection substrate 400, which is a separate component configured to electrically connect the sensing terminal and the eccentricity measurement sensor 100, is included in the sensing terminal and the eccentricity measurement sensor 100, the sensing terminal, which extends in a circumferential direction, and the eccentricity measurement sensor 100, which extends in an axial direction, may be separately and temporarily assembled to the stator S and then connected to the connection substrate 400. Therefore, the assembling convenience may be maximized.

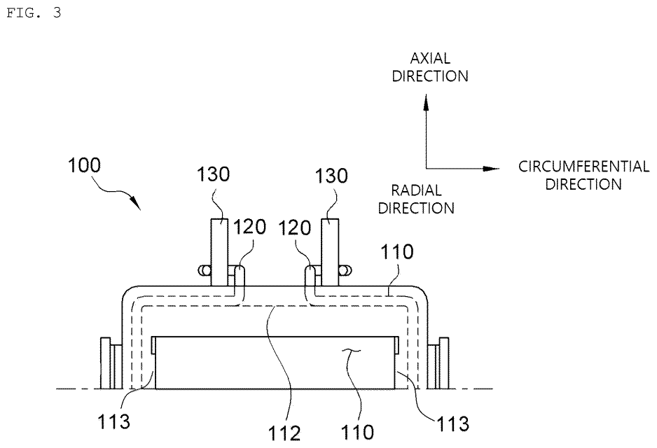

In more detail, as illustrated in FIG. 3, the eccentricity measurement sensor 100 may include a sensor housing 110 including an insertion hole 111 penetratively formed so that the shoe of the stator S is fitted with the insertion hole 111. In more detail, the sensor housing 110 of the eccentricity measurement sensor 100 may be coupled to the shoe of the stator S in the radial direction and fitted with the shoe of the stator S radially inside the stator S. The insertion hole 111 may be formed in a shape identical to a shape of a surface perpendicular to the radial direction of the shoe of the stator S, and the sensor housing 110 may be formed in a quadrangular ring shape along an edge of the surface perpendicular to the radial direction of the shoe of the stator S. The eccentricity measurement sensor 100 may be inserted into a motor housing as described above, thereby minimizing interference with other components.

In addition, the eccentricity measurement sensor 100 of the present disclosure may include the sensor coils 120 and pins 130. The sensor coil 120 may be wound around the sensor housing 110 and generate a magnetic field between the sensor coil 120 and the rotor R. In more detail, the sensor coils 120 may be disposed to extend along outer peripheries of a surface of the shoe of the stator S and a surface of the rotor R that face each other. Therefore, the sensor coil 120 may generate an induced electromotive force by a change in magnetic field generated in a direction perpendicular to a surface of the shoe of the stator S that faces a lateral surface of the rotor R, and the eccentricity measurement sensor 100 may consistently measure a change in induced electromotive force through magnetic induction by means of a change in magnetic field generated in all regions over the upper end R1 of the rotor and the lower end R2 of the rotor (based on the axial direction), such that magnetic flux is generated in the radial direction, thereby measuring all tilt eccentricity, static eccentricity, and dynamic eccentricity. In addition, the pins 130 may be coupled to the sensor housing 110, protrude from one surface of the sensor housing 110, be electrically connected to the sensor coil 120, and transmit a magnetic field signal of the sensor coil 120 to the outside.

In addition, the sensor housing 110 of the eccentricity measurement sensor 100 may include a bobbin portion 112 that is a groove concavely formed along the outer peripheries of the surface of the shoe of the stator S and the surface of the rotor R that face each other, and the bobbin portion 112 has one surface that adjoins the sensor coil 120. The bobbin portion 112 may be formed such that a depth of a center based on the radial direction is deeper than a depth of an outer periphery based on the radial direction. For example, the surface, which adjoins the sensor coil 120, may be formed to be round (‘U’ shape) or formed in a ‘V’ shape. Therefore, the sensor coil 120 wound around the bobbin portion 112 may be guided to be positioned at the center of the bobbin portion 112, i.e., the center based on the radial direction. Therefore, even though the motor housing and the stator S vibrate, the sensor coil 120 is not separated, and a position of the sensor coil 120 may be constantly maintained, thereby improving accuracy in measuring eccentricity. In addition, the sensor housing 110 may include protruding portions 113 protruding from the insertion hole 111 toward the shoe of the stator S and having protruding surfaces that adjoin the shoe of the stator S. Because the protruding portion 113 is included, the eccentricity measurement sensor 100 may be fixed to a radial distal end of the shoe of the stator S.

In addition, the eccentricity measurement sensor 100 may be fixed to the shoe of the stator S in the radial direction at an inner diameter position of a core of the stator S. Thereafter, the stator S and the eccentricity measurement sensor 100 may be fixed by using an impregnation liquid when the stator S is impregnated. In this case, the impregnation liquid may be allowed to flow to the bobbin portion 112 of the eccentricity measurement sensor 100, such that the sensor coil 120 wound around the bobbin portion 112 may also be simultaneously fixed. Therefore, the eccentricity measurement sensor 100 may be moved toward an outer diameter portion and completely prevented from being separated from the shoe of the stator S, thereby improving accuracy in measuring eccentricity.

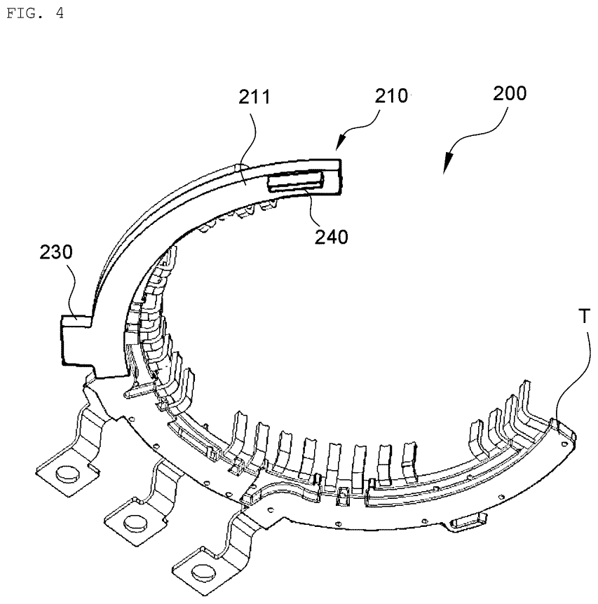

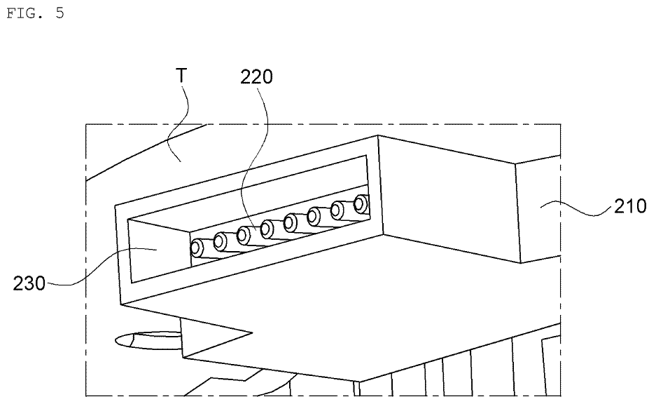

Hereinafter, the first sensing terminal 200 of the present disclosure will be described in more detail with reference to FIGS. 4 to 5.

As illustrated in FIG. 4, the first sensing terminal 200 may include an electrode pattern 220 electrically connected to the eccentricity measurement sensor 100, and an integrated housing 210 formed with the electrode pattern 220 by insert-molding. In this case, the integrated housing 210 may be manufactured simultaneously with the terminal assembly T of the stator S, and the integrated housing 210 may be formed as a single component and made of an insulating material. For example, the integrated housing 210 may be a plastic housing. The electrode pattern 220, which is a conductor, is inserted into a mold, and the integrated housing 210 may be formed together with the electrode pattern 220 by injection-molding. The electrode pattern 220 may be manufactured by performing blanking on a copper plate by using a press. Because the integrated housing 210 is included, the position of the electrode pattern 220 may be fixed to a configuration of the terminal assembly T provided in advance.

In addition, the integrated housing 210 may include an arc portion 211 formed in an arc shape along a circumferential edge of the stator S. In this case, a center of the arc portion 211 may be consistent with a rotation axis of the rotor R. Because the integrated housing 210 includes the arc portion 211, the integrated housing 210 may be smoothly formed integrally with the terminal assembly T in the related art, thereby minimizing interference with the motor coil.

In addition, as illustrated in FIG. 5, the integrated housing 210 may include an external terminal 230 into which a circuit pattern 311 is inserted and an electrode of an external component is inserted. The external terminal 230 may be formed by extending the electrode pattern 220 to the outside in the radial direction of a ring portion 313, and a plastic injection-molded product of the integrated housing 210 may be formed to surround the external terminal 230. Therefore, a connector or the like may be easily inserted into the external terminal 230, such that the sensing terminal and other components may be electrically connected, and the sensing information may be smoothly transferred to the outside.

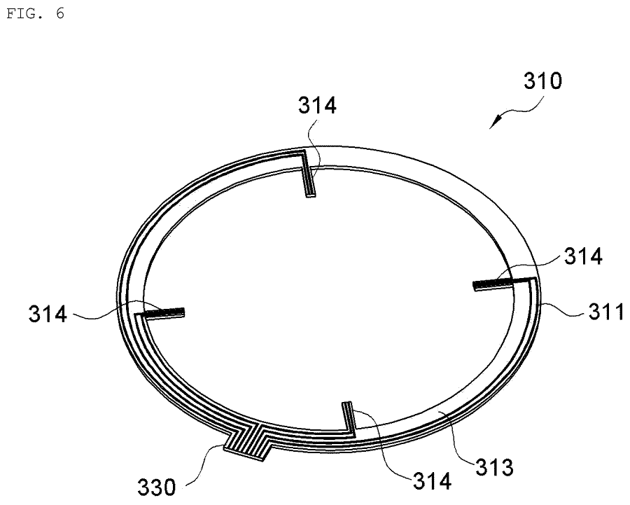

Hereinafter, the second sensing terminal 300 of the present disclosure will be described in more detail with reference to FIGS. 6 to 8.

As illustrated in FIG. 6, the second sensing terminal 300 may include a flat plate-type substrate part 310 electrically connected to the eccentricity measurement sensor 100 and including the circuit pattern 311 printed on one surface. The substrate part 310 may be a PCB and include the circuit pattern 311 printed on one surface. The substrate part 310 may include the ring portion 313 formed in a ring shape along the circumferential edge of the stator S, and sensor connection portions 314 extending in the radial direction from the ring portion 313 toward the eccentricity measurement sensor 100. Because the ring portion 313 is included, it is possible to minimize interference between the sensing terminal and the wound motor coil.

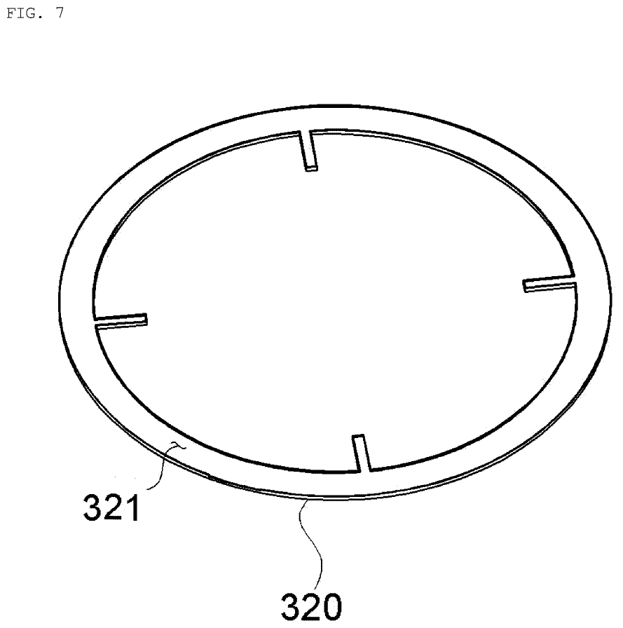

In addition, as illustrated in FIG. 7, the second sensing terminal 300 may include a mounting part 320 formed in a shape corresponding to the substrate part 310 and including a predetermined accommodation space 321 configured to accommodate the substrate part 310, and the mounting part 320 may be made of an insulating material and have one surface that adjoins an axial distal end surface of the stator S. The mounting part 320 may be a plastic injection-molded product and be provided as an insulator. Therefore, the substrate part 310 and the stator S made of steel may be insulated from each other. In addition, because the mounting part 320 is included, the position of the substrate part 310 may be stably fixed onto the stator S. In addition, the mounting part 320 may have a partition wall for supporting the position of the substrate part 310 along an edge of the accommodation space 321. In addition, the mounting part 320 may further include a fixing portion 322 protruding from an inner surface in order to more assuredly fix the position of the substrate part 310.

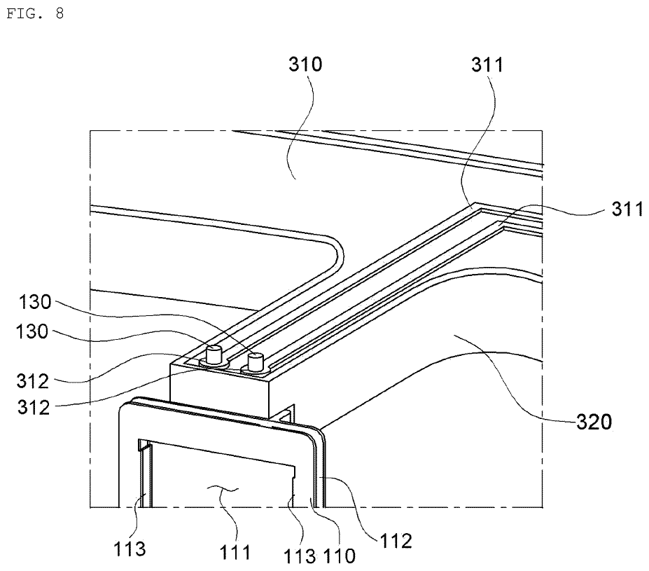

In addition, as illustrated in FIG. 8, the eccentricity measurement sensor 100 may include the pins 130 extending toward the second sensing terminal 300, the substrate part 310 may include via holes 312 formed through a surface that adjoins the eccentricity measurement sensor 100, and the pins 130 may be fitted with the via holes 312 and soldered. In this case, the substrate part 310 may be formed to extend to cover the eccentricity measurement sensor 100, the circuit pattern 311 may extend to the via holes 312, and the pins 130 may be fitted with the via holes 312 and coupled by soldering. In an example of the substrate part 310, in case that a plurality of eccentricity measurement sensors 100 are connected to one second sensing terminal 300, the sensor connection portions 314, the via holes 312, and the circuit patterns 311 coupled to the respective eccentricity measurement sensors 100 may be formed independently. One end of each of the circuit patterns 311 may be connected to the eccentricity measurement sensor 100, the other end of each of the circuit patterns 311 may extend toward the second internal terminal, and the circuit patterns 311 may be formed so as not to interfere with one another.

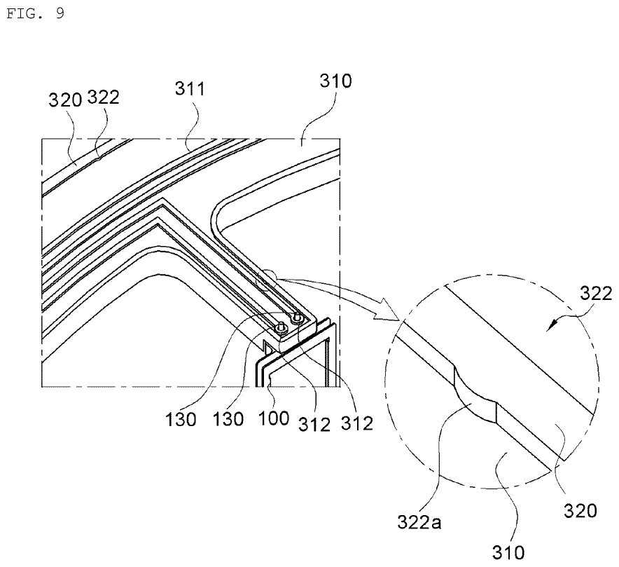

As illustrated in FIGS. 9 to 11, the mounting part 320 may include at least one fixing portion 322 extending from an inner surface of the accommodation space 321 and configured to fix the position of the substrate part 310. In more detail, in a first embodiment of the fixing portion 322 illustrated in FIG. 9, the fixing portion 322 may include a first protruding portion 322a including a curved surface having a predetermined curvature. A width of a side of the first protruding portion 322a, which adjoins the stator, and a width of a side of the first protruding portion 322a, which does not adjoin the stator, may be equal to each other. Because the first protruding portion 322a is included, the substrate part 310 may be caught by the first protruding portion 322a without being separated. At least one first protruding portion 322a may be formed on the ring portion 313, and at least one first protruding portion 322a may be formed on the sensor connection portion 314.

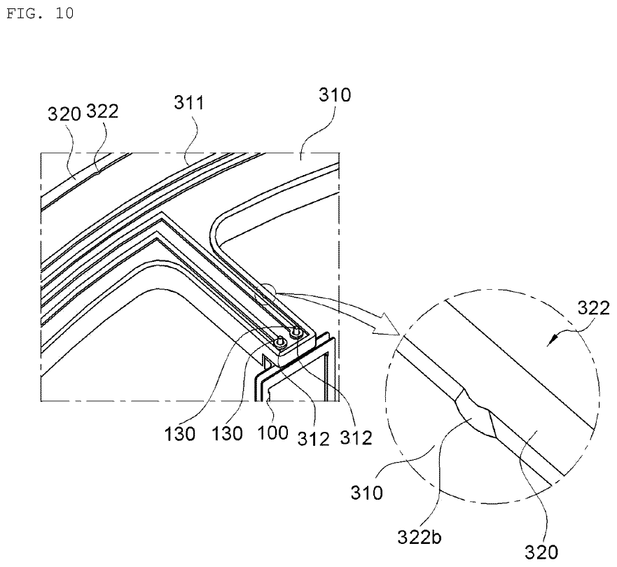

In addition, in a second embodiment of the fixing portion 322 illustrated in FIG. 10, the fixing portion 322 may include a second protruding portion 322b including a curved surface having a predetermined curvature. A width of a side of the second protruding portion 322b, which does not adjoin the stator, may be smaller than a width of a side of the second protruding portion 322b that adjoins the stator. Because the second protruding portion 322b is included, the substrate part 310 may be caught by the second protruding portion 322b without being separated. The draft angle may be applied as described above, thereby improving assemblability between the substrate part 310 and the mounting part 320. In addition, at least one second protruding portion 322b may be formed on the ring portion 313, and at least one second protruding portion 322b may be formed on the sensor connection portion 314.

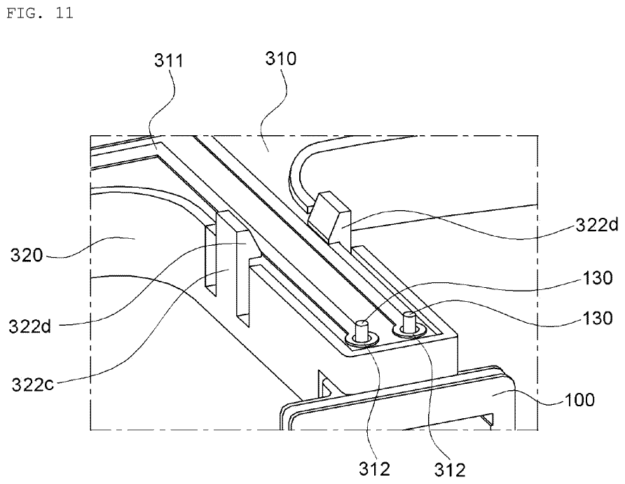

In addition, in a third embodiment of the fixing portion 322 illustrated in FIG. 11, the fixing portion 322 may include a springback portion 322c extending from the inner surface of the accommodation space 321 of the mounting part 320, and a projection 322d protruding from a distal end of the springback portion 322c so as to adjoin one surface of the substrate part 310. Slits may be formed between the springback portion 322c and a wall surface of the mounting part 320 and allow the springback portion 322c to be bent even by low pressure. The springback portion 322c may be elastically deformed while being bent to the outside of the mounting part 320 when pressure is applied to the projection 322d. Therefore, when the substrate part 310 is assembled to the accommodation space 321 of the mounting part 320, the springback portion 322c may be stretched outward to facilitate assemblability. After the substrate part 310 is assembled in the accommodation space 321, no pressure is applied to the springback portion 322c, such that the projection 322d and the substrate part 310 may be caught. The springback portion 322c and the projection 322d may be applied together with the first protruding portion 322a and the second protruding portion 322b, and the number of springback portions 322c and the number of projections 322d may be minimized and applied. Therefore, it is possible to improve the assemblability between the substrate part 310 and the mounting part 320.

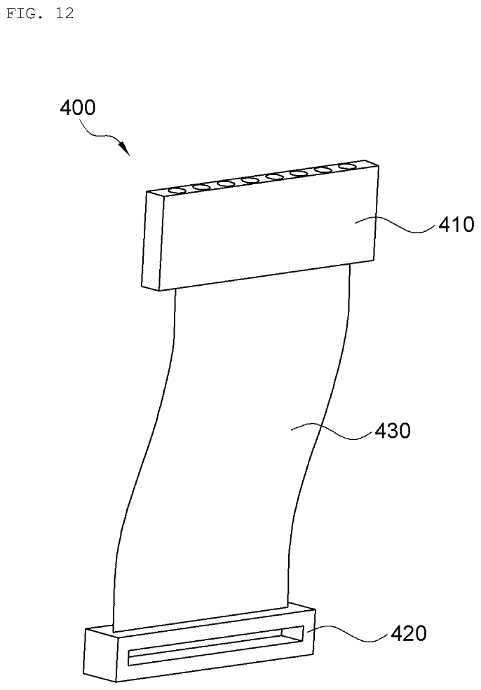

Hereinafter, coupling relationships between the connection substrate 400 and the first sensing terminal 200 and between the second sensing terminal 300 and the connection substrate 400 of the present disclosure will be described in more detail with reference to FIGS. 12 to 15.

As illustrated in FIG. 12, the connection substrate 400 may include a first connection part 410 provided at one end of the connection substrate 400 and electrically connected to the first sensing terminal 200, and a second connection part 420 provided at the other end of the connection substrate 400 and electrically connected to the second sensing terminal 300. In addition, the connection substrate 400 may include a signal transmission part 430 having two opposite ends electrically connected to the first connection part 410 and the second connection part 420, and a wiring circuit may be embedded in the signal transmission part 430. The signal transmission part 430 may be an FPCB. Because the signal transmission part 430 is configured as an FPCB, the first sensing terminal 200 and the second sensing terminal 300, which are spaced apart from each other, may be more smoothly connected.

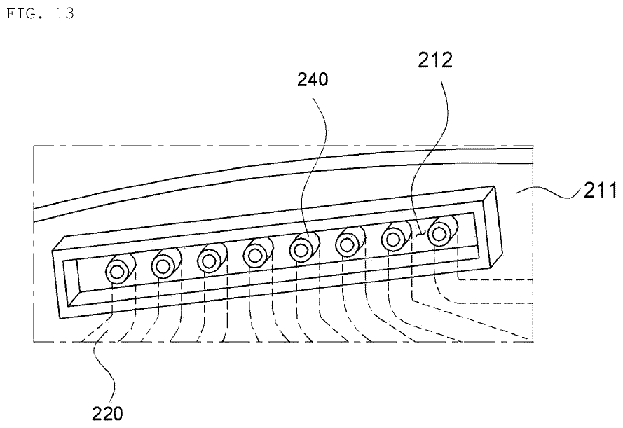

In addition, as illustrated in FIG. 13, the first sensing terminal 200 may include first internal terminals 240 electrically connected to the electrode pattern and formed to be withdrawn to the outside of the arc portion 211. More clearly, the first internal terminal 240 may be formed to be withdrawn in the axial direction from the arc portion 211. In addition, the integrated housing 210 may include a first connector insertion groove 212 protruding from one surface of the ring portion 313, formed outside the first internal terminals 240, and formed to have an inner surface shape corresponding to an outer surface shape of the first connection part 410. In this case, the first connection part 410 may be a connector and include grooves concavely formed in the axial direction so that the first internal terminals 240 are inserted into the grooves.

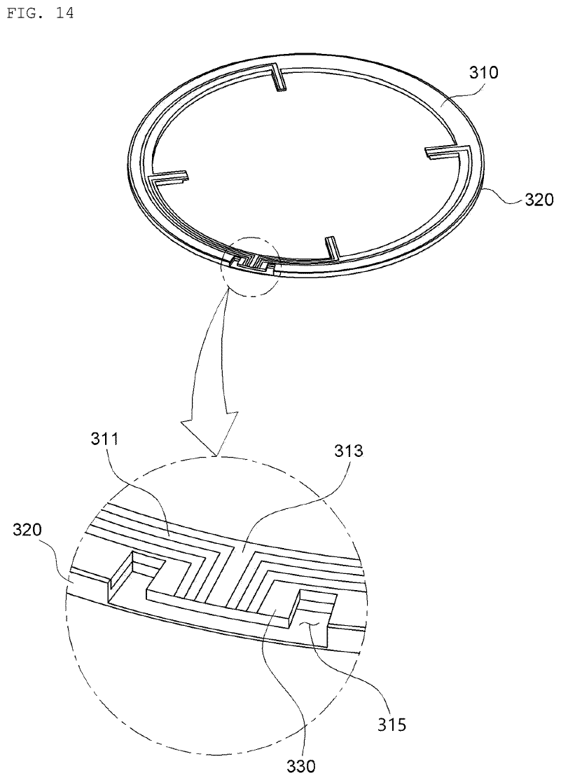

In addition, as illustrated in FIG. 14, the second sensing terminal 300 may include second internal terminals 330 electrically connected to the circuit pattern 311. In this case, the substrate part 310 may include second connector insertion grooves 315 concavely formed radially inward along outer peripheral surfaces of the second internal terminals 330. In addition, the second connection part 420 may be a connector and include grooves concavely formed in the radial direction so that the second internal terminals 330 are inserted into the grooves. In addition, the mounting part 320 may be formed such that a partition wall in a region corresponding to a region, in which the second connector insertion groove 315 is formed, is lower than a partition wall in a region corresponding to a region in which the second connector insertion groove 315 is not formed. Therefore, the second connection part 420, which is a connector, may be easily coupled to the second connector insertion groove 315 in the radial direction.

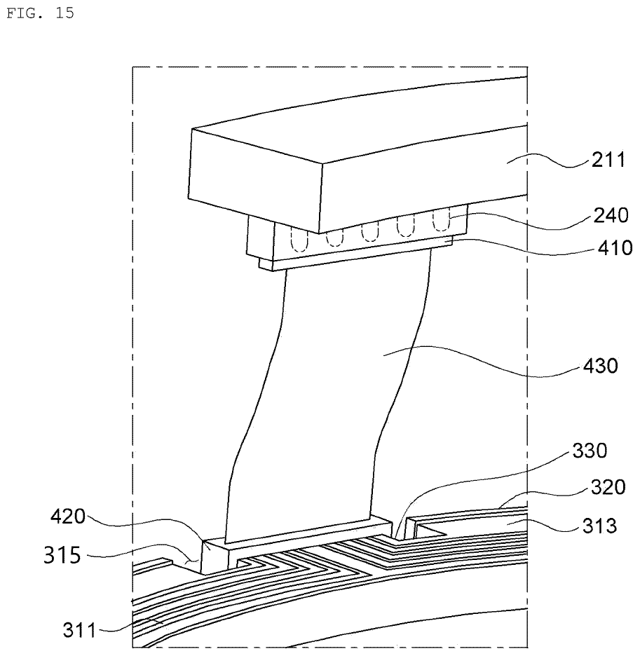

Therefore, as illustrated in FIG. 15, the first connection part 410 and the second connection part 420 of the connection substrate 400 are respectively assembled with the first sensing terminal 200 and the second sensing terminal 300, such that the eccentricity measurement sensor 100, the second sensing terminal 300, the first sensing terminal 200, and the external controller may be electrically connected. With the above-mentioned configuration of the eccentricity measurement system 1000, the first sensing terminal 200, the terminal assembly T, the second sensing terminal 300, and the eccentricity measurement sensor 100 are assembled in advance and mounted on the stator S, and then the first sensing terminal 200 and the second sensing terminal 300 may be connected to the connection substrate 400, thereby further simplifying the assembling process and remarkably reducing a probability of a defect.

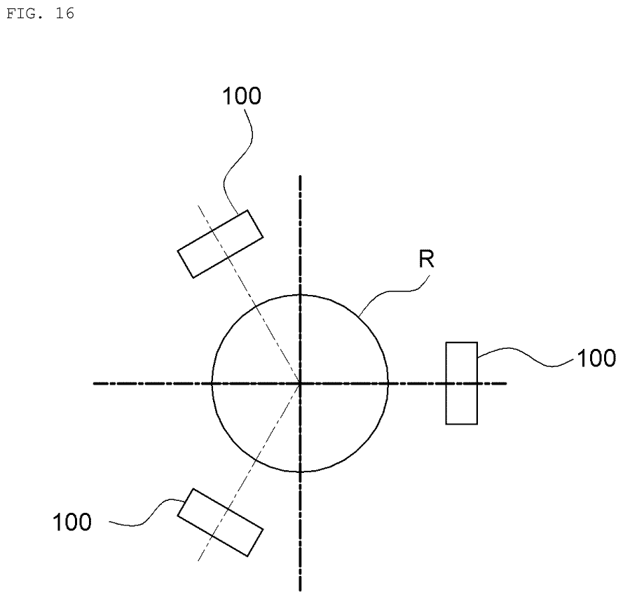

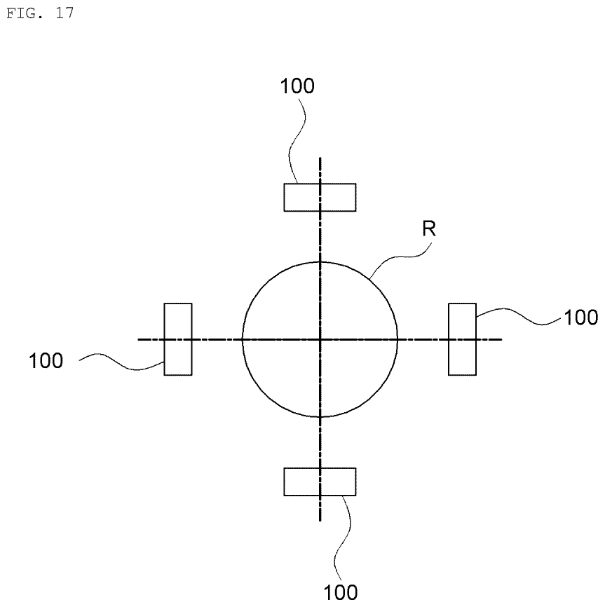

Hereinafter, embodiments of an arrangement of the eccentricity measurement sensor 100 of the present disclosure will be described in more detail with reference to FIGS. 16 and 17.

As illustrated in FIGS. 16 and 17, two or more eccentricity measurement sensors 100 may be disposed in the stator S, and the respective eccentricity measurement sensors 100 may be disposed to be spaced apart from one another at equal intervals. Because two or more eccentricity measurement sensors 100 are applied, the eccentric state may be identified by comparing data between the sensors in case that it is difficult to identify reference data when no eccentricity is present. In more detail, as illustrated in FIG. 16, in case that three eccentricity measurement sensors 100 are applied, the eccentricity measurement sensors 100 may be positioned at positions with a phase difference of 120 degrees based on the stator S and the rotation axis of the rotor R. Alternatively, as illustrated in FIG. 17, in case that four eccentricity measurement sensors 100 are applied, the eccentricity measurement sensors 100 may be positioned at positions with a phase difference of 90 degrees based on the stator S and the rotation axis of the rotor R. Likewise, in case that two eccentricity measurement sensors 100 are applied, the eccentricity measurement sensors 100 may be positioned at positions with a phase difference of 180 degrees based on the stator S and the rotation axis of the rotor R.

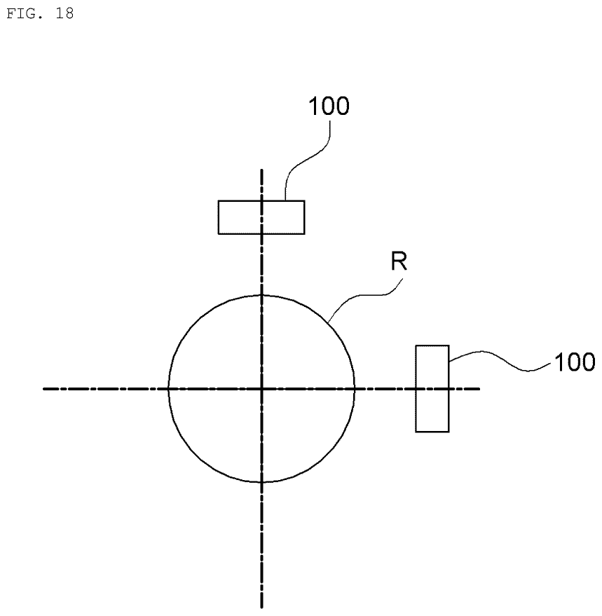

In addition, as illustrated in FIG. 18, two or more eccentricity measurement sensors 100 may be disposed in the stator S and disposed to be spaced apart from one another while having a phase difference of 90 degrees. Therefore, the eccentric state may be identified by comparing data between the sensors in case that it is difficult to identify the reference data when no eccentricity is present.

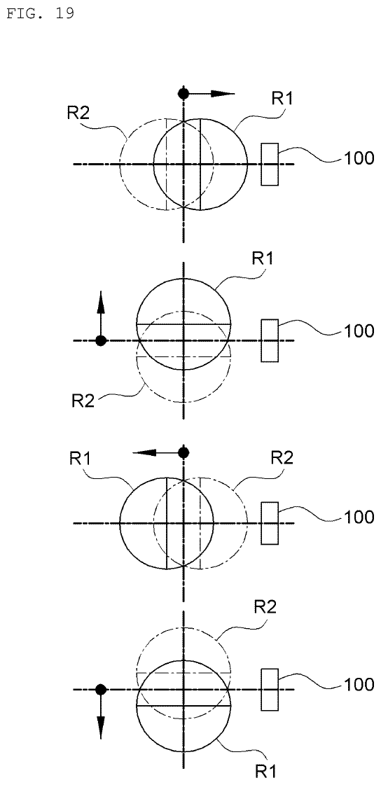

Hereinafter, an algorithm for measuring the eccentricity of the rotor R by using the eccentricity measurement sensor 100 of the present disclosure will be described with reference to FIGS. 19 to 26.

As illustrated in FIG. 19, in case that one eccentricity measurement sensor 100 is applied and the upper end R1 and the lower end R2 of the rotor are inclined to the same degree in opposite (radial) directions (tilt eccentricity case 1), the magnetic flux amount at the side close to the eccentricity measurement sensor 100 may increase, and the magnetic flux amount at the side distant from the eccentricity measurement sensor 100 may decrease. That is, the overall magnetic flux amount may change.

In more detail, in case that eccentricity occurs in a leftward/rightward direction in FIG. 19, an aspect may be measured in which the magnetic flux amount only at any one of the upper end R1 or the lower end R2 of the rotor R increases, and the magnetic flux amount at the other of the upper end R1 or the lower end R2 of the rotor R decreases. That is, it can be ascertained that in case that the magnetic flux amount at the upper end R1 of the rotor increases and the magnetic flux amount at the lower end R2 of the rotor decreases, the upper end R1 of the rotor is inclined toward the eccentricity measurement sensor 100. In the opposite case, it can be ascertained that the lower end R2 of the rotor is inclined toward the eccentricity measurement sensor 100.

In addition, in case that eccentricity occurs in an upward/downward direction in FIG. 19, both the upper end R1 and the lower end R2 of the rotor R are distant from the eccentricity measurement sensor 100, such that the magnetic flux amounts may decrease at both the upper end R1 and the lower end R2 of the rotor R. Therefore, it can be ascertained that the eccentricity occurs in a direction perpendicular to the direction in which the rotor R faces the eccentricity measurement sensor 100.

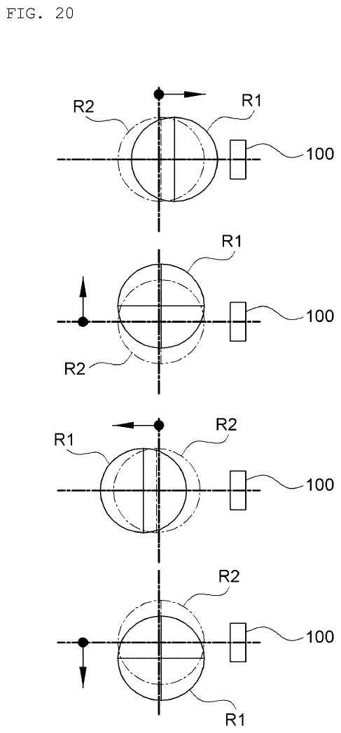

As illustrated in FIG. 20, in case that one eccentricity measurement sensor 100 is applied and only any one of the upper end R1 and the lower end R2 of the rotor R is inclined (tilt eccentricity case 2), the inclined side of the rotor R becomes close to or distant from the eccentricity measurement sensor 100, such that the magnetic flux amount may increase or decrease.

In more detail, in case that eccentricity occurs, an aspect may be measured in which the magnetic flux amount only at any one of the upper end R1 or the lower end R2 of the rotor R increases or decreases, and the magnetic flux amount at the other of the upper end R1 or the lower end R2 of the rotor R is maintained. That is, it can be ascertained that in case that the magnetic flux amount at the upper end R1 of the rotor increases or decreases and the magnetic flux amount at the lower end R2 of the rotor is maintained, the upper end R1 of the rotor is inclined. In the opposite case, it can be ascertained that the lower end R2 of the rotor is inclined.

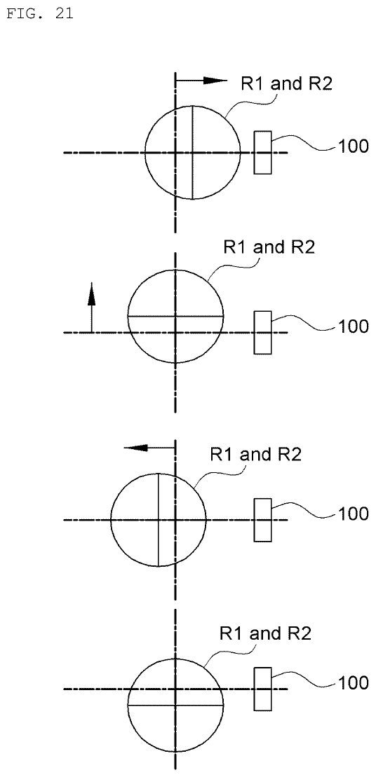

As illustrated in FIG. 21, in case that one eccentricity measurement sensor 100 is applied and both the upper end R1 and the lower end R2 of the rotor R are constantly eccentric, i.e., in case that the rotor R is eccentric in the radial direction (static eccentricity), both the upper end R1 and the lower end R2 of the rotor R become close to or distant from the eccentricity measurement sensor 100 in the same way, such that the magnetic flux amount may increase or decrease. That is, it can be ascertained that the rotor R is statically eccentric toward the eccentricity measurement sensor 100 when the magnetic flux amounts at the upper end R1 and the lower end R2 of the rotor simultaneously increase in the same way, and the rotor R is statically eccentric in a direction away from the eccentricity measurement sensor 100 when the magnetic flux amounts at the upper end R1 and the lower end R2 of the rotor simultaneously decrease in the same way.

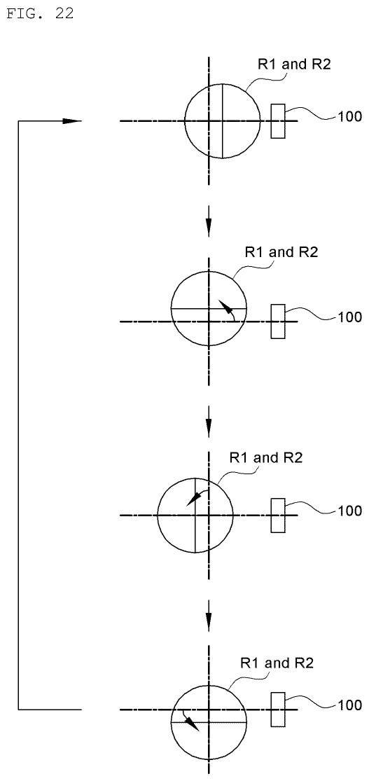

In addition, as illustrated in FIG. 22, in case that one eccentricity measurement sensor 100 is applied and a value of an air gap changes over time (dynamic eccentricity), the magnetic flux amount measured from the rotor R may change over time, and the cycle of the magnetic flux amount may also change. In more detail, when the rotor R becomes close to the eccentricity measurement sensor 100, the magnetic flux amount may increase at the same time when the cycle of the magnetic flux amount is shortened. When the rotor R becomes distant from the eccentricity measurement sensor 100 in the opposite direction, the magnetic flux amount may decrease at the same time when the cycle of the magnetic flux amount is lengthened.

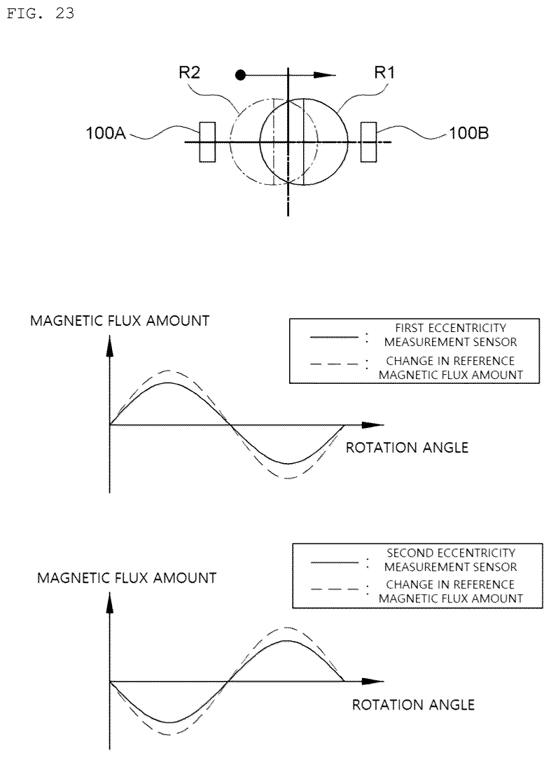

In addition, as illustrated in FIG. 23, in case that two eccentricity measurement sensors 100 are applied and the upper and lower sides of the rotor R are inclined to the same degree in opposite (radial) directions (tilt eccentricity case 1), the magnetic flux amount close at the side to the eccentricity measurement sensor 100 may increase, and the magnetic flux amount at the side distant from the eccentricity measurement sensor 100 may decrease. That is, the overall magnetic flux amount may change.

For example, in case that a first eccentricity measurement sensor 100A and a second eccentricity measurement sensor 100B are disposed to be spaced apart from each other with a phase difference of 180 degrees and the tilt eccentricity of the rotor R occurs at the first eccentricity measurement sensor 100A and the second eccentricity measurement sensor 100B, the magnetic flux amount may partially decrease in comparison with a reference magnetic flux amount determined when no eccentricity occurs at both the first eccentricity measurement sensor 100A and the second eccentricity measurement sensor 100B. This represents an aspect in which the magnetic flux amount decreases as the upper end R1 or the lower end R2 of the rotor R becomes distant from the first eccentricity measurement sensor 100A and the second eccentricity measurement sensor 100B.

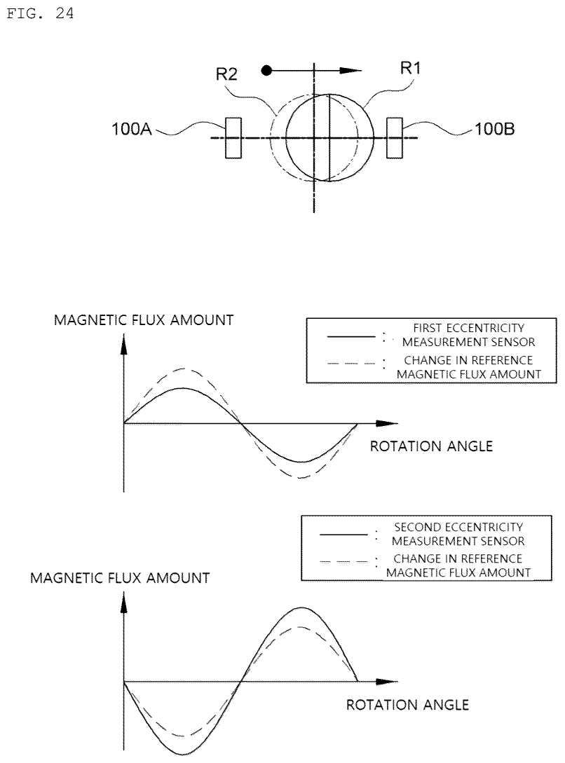

In addition, as illustrated in FIG. 24, in case that two eccentricity measurement sensors 100 are applied and only any one of the upper end R1 and the lower end R2 of the rotor R is inclined (tilt eccentricity case 2), the magnetic flux amount at the side close to the eccentricity measurement sensor 100 may increase, the magnetic flux amount at the side distant from the eccentricity measurement sensor 100 may decrease, and the magnetic flux amount at another side may be maintained. For example, in case that the first eccentricity measurement sensor 100A and the second eccentricity measurement sensor 100B are disposed to be spaced apart from each other with a phase difference of 180 degrees and the eccentricity of the upper end R1 of the rotor occurs so that the upper end R1 of the rotor becomes close to the second eccentricity measurement sensor 100B, the magnetic flux amount at the first eccentricity measurement sensor 100A may become partially smaller than a reference value, and the magnetic flux amount at the second eccentricity measurement sensor 100B may become partially larger than the reference value.

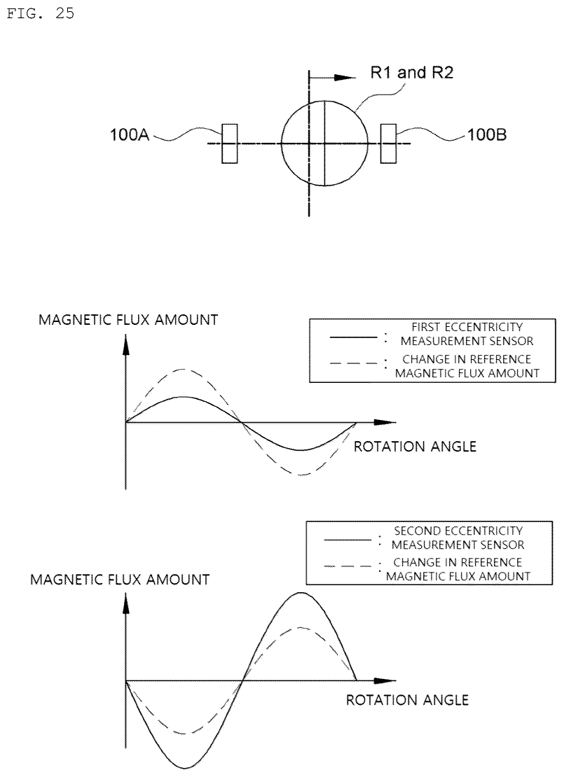

In addition, as illustrated in FIG. 25, in case that two eccentricity measurement sensors 100 are applied and both the upper end R1 and the lower end R2 of the rotor R are constantly eccentric, i.e., in case that the rotor R is eccentric in the radial direction (static eccentricity), both the upper end R1 and the lower end R2 of the rotor R become close to or distant from the eccentricity measurement sensor 100 in the same way, such that the magnetic flux amount may increase or decrease. That is, the magnetic flux amounts at the upper end R1 and the lower end R2 of the rotor may simultaneously increase in the same way. For example, in case that the first eccentricity measurement sensor 100A and the second eccentricity measurement sensor 100B are disposed to be spaced apart from each other with a phase difference of 180 degrees and the eccentricity of the rotor occurs so that the rotor becomes close to the second eccentricity measurement sensor 100B, the magnetic flux amount at the first eccentricity measurement sensor 100A may become significantly smaller than a reference value, and the magnetic flux amount at the second eccentricity measurement sensor 100B may become significantly larger than the reference value.

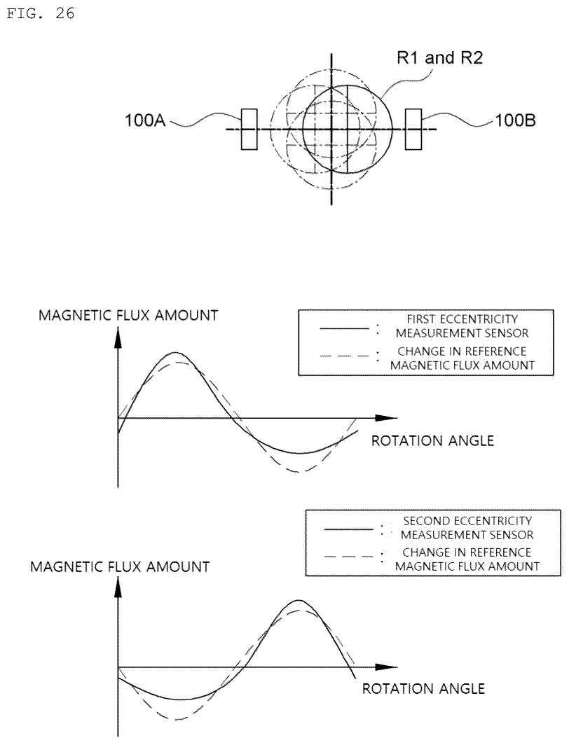

In addition, as illustrated in FIG. 26, in case that two eccentricity measurement sensors 100 are applied and a value of an air gap changes over time (dynamic eccentricity), the magnetic flux amount measured from the rotor R may change over time, and both the rotation angle and the magnetic flux amount may change over time. For example, in case that the first eccentricity measurement sensor 100A and the second eccentricity measurement sensor 100B are disposed to be spaced apart from each other with a phase difference of 180 degrees and dynamic eccentricity occurs in the rotor R, the magnetic flux amount graphs of the first eccentricity measurement sensor 100A and the second eccentricity measurement sensor 100B may be formed in opposite directions and different in magnetic flux amount and cycle from the reference value.

Furthermore, at least two or more of the tilt eccentricity, the static eccentricity, and the dynamic eccentricity may occur while overlapping one another. In this case, the type of eccentricity may be analyzed by comparing each of the eccentricity data with the measured data.

The eccentricity measurement system of the present disclosure may include the eccentricity measurement sensor mounted in the motor and configured to measure all the tilt eccentricity, the static eccentricity, and the dynamic eccentricity of the rotor by using a change in magnetic field generated between the rotor and the stator, thereby overcoming a limitation of a reflective laser sensor method in the related art, reducing costs in comparison with the reflective laser sensor in the related art, detecting the eccentricity factor that most significantly affects noise and vibration of the rotary device, detecting a defect at the initial stage of mass production to prevent shipment of potentially defective products, measuring eccentricity caused by abrasion or the like after product durability testing or after prolonged operation of the vehicle to detect in advance a problem, and taking in advance an action such as repair.

In addition, with the above-described eccentricity measurement system, when the eccentricity measurement system is applied to the autonomous vehicles in the future, it is possible to monitor a mechanical state of the rotary device, apply the eccentricity measurement system to a smart rotary device system capable of evaluating a state thereof by using the pre-secured defect level index, and recognize the state of the rotary device in a region imperceptible to humans. Furthermore, the eccentricity measurement system may be applied in a case in which it is difficult to recognize a state of the individual rotary device because of external vibration or noise, such that the eccentricity measurement system may be used to detect and address problems in the electric motor used in urban air mobility (UAM) aircraft in advance.

The technical spirit should not be construed as being limited to the embodiments of the present disclosure. Of course, the scope of application is diverse, and various modifications and implementations may be made by those skilled in the art without departing from the subject matter of the present disclosure claimed in the claims. Accordingly, these improvements and modifications will fall within the scope of the present disclosure as long as they are apparent to those skilled in the art.

What is claimed is:

1. An eccentricity measurement system, which is applied to a motor system comprising a stator and a rotor and measures eccentricity of the rotor, the eccentricity measurement system comprising:
an eccentricity measurement sensor fitted with a shoe of the stator and configured to measure a presence or absence of eccentricity of the rotor by measuring a change in magnetic field generated between the rotor and the stator;
a first sensing terminal formed integrally with a terminal assembly of the stator and configured to transfer sensing information of the eccentricity measurement sensor to the outside;
a second sensing terminal having one surface that adjoins an axial distal end surface of the stator, the second sensing terminal being configured to transfer sensing information of the eccentricity measurement sensor to the first sensing terminal; and
a connection substrate configured to electrically connect the first sensing terminal and the second sensing terminal.

2. The eccentricity measurement system of claim 1, wherein the first sensing terminal comprises:
an integrated housing formed with a predetermined electrode pattern by insert molding, formed integrally with the terminal assembly of the stator, and made of an insulating material; and
an external terminal into which the electrode pattern is inserted and an electrode of an external component is inserted, and
wherein the integrated housing comprises an arc portion formed in an arc shape along a circumferential edge of the stator.

3. The eccentricity measurement system of claim 2, wherein the second sensing terminal comprises:
a flat plate-type substrate part electrically connected to the eccentricity measurement sensor and comprising a circuit pattern printed on one surface; and
a mounting part formed in a shape corresponding to the substrate part, comprising a predetermined accommodation space configured to accommodate the substrate part, having a partition wall disposed along an edge of the accommodation space, having one surface adjoining an axial distal end surface of the stator, and made of an insulating material.

4. The eccentricity measurement system of claim 3, wherein the eccentricity measurement sensor comprises a pin extending toward the second sensing terminal, and
wherein the substrate part comprises a via hole formed through a surface adjoining the eccentricity measurement sensor, the via hole being configured such that the pin is fitted with the via hole and soldered.

5. The eccentricity measurement system of claim 3, wherein the substrate part comprises:
a ring portion formed in a ring shape along the circumferential edge of the stator; and
a sensor connection portion extending in a radial direction from the ring portion toward the eccentricity measurement sensor.

6. The eccentricity measurement system of claim 5, wherein the connection substrate comprises:
a first connection part provided at one end and electrically connected to the first sensing terminal;
a second connection part provided at the other end and electrically connected to the second sensing terminal; and
a signal transmission part electrically connected to the first connection part and the second connection part and having therein an embedded wiring circuit.

7. The eccentricity measurement system of claim 6, wherein the first sensing terminal comprises a first internal terminal electrically connected to the electrode pattern and formed to be withdrawn to the outside of the arc portion,
wherein the integrated housing comprises a first connector insertion groove protruding from one surface of the ring portion, disposed outside the first internal terminal, and having an inner surface shape corresponding to an outer surface shape of the first connection part, and
wherein the first connection part is a connector comprising a groove concavely formed in an axial direction so that the first internal terminal is inserted into the groove.

8. The eccentricity measurement system of claim 6, wherein the second sensing terminal comprises a second internal terminal electrically connected to the circuit pattern,
wherein the substrate part comprises a second connector insertion groove concavely formed radially inward along an outer peripheral surface of the second internal terminal,
wherein the mounting part is formed such that the partition wall in a region, which corresponds to a region in which the second connector insertion groove is formed, is formed to be lower than the partition wall in a region corresponding to a region in which the second connector insertion groove is not formed, and
wherein the second connection part is a connector comprising a groove concavely formed in the radial direction so that the second internal terminal is inserted into the groove.

9. The eccentricity measurement system of claim 3, wherein the mounting part comprises at least one fixing portion extending from an inner surface of the accommodation space and configured to fix a position of the substrate part.

10. The eccentricity measurement system of claim 9, wherein the fixing portion comprises a first protruding portion comprising a curved surface having a predetermined curvature, and
wherein a width of a side of the first protruding portion, which adjoins the stator, and a width of a side of the first protruding portion, which does not adjoin the stator, are equal to each other.

11. The eccentricity measurement system of claim 9, wherein the fixing portion comprises a second protruding portion comprising a curved surface having a predetermined curvature, and
wherein a width of a side of the second protruding portion, which does not adjoin the stator, is smaller than a width of a side of the second protruding portion that adjoins the stator.

12. The eccentricity measurement system of claim 9, wherein the fixing portion comprises:
a springback portion extending from the inner surface of the accommodation space of the mounting part; and
a projection protruding from a distal end of the springback portion so as to adjoin one surface of the substrate part.

13. The eccentricity measurement system of claim 1, wherein the eccentricity measurement sensor is provided as two or more eccentricity measurement sensors disposed in the stator, and the respective eccentricity measurement sensors are disposed to be spaced apart from one another at equal intervals.

14. The eccentricity measurement system of claim 1, wherein the eccentricity measurement sensor is provided as two or more eccentricity measurement sensors disposed in the stator and disposed to be spaced apart from one another while having a phase difference of 90 degrees.
